(19) United States
(12) Patent Application Publication
(10) Pub. No.: US 2019/0198695 A1
(43) Pub. Date: Jun. 27, 2019

(54) BIFACIAL SOLAR CELL MODULE

(71) Applicant: SHARP KABUSHIKI KAISHA, Sakai City (JP)

(72) Inventor: YASUSHI YOSHIKAWA, Sakai City (JP)

(21) Appl. No.: 16/232,330

(22) Filed: Dec. 26, 2018

(30) Foreign Application Priority Data
Dec. 27, 2017 (JP) 2017-251075

(51) Int. Cl. H01L 31/05; H01L 31/0224; H01L 31/049

(52) U.S. Cl. CPC H01L 31/0508; H01L 31/049; H01L 31/022441

(57) ABSTRACT

A solar cell module includes a plurality of back contact solar cells each of which includes an electrode, and a wiring substrate in which a plurality of wires are fixed to one surface of a wiring base member that is light transmissive. The wires are conductors each of which has a circular cross-sectional shape. The wiring substrate includes a light-transmissive portion in which wires are not disposed on the wiring base member. Each of the solar cells includes a light-receiving region in which the electrode is not disposed.

### BACKGROUND

### 1. Field

The present disclosure relates to a bifacial solar cell module including a back contact solar cell that is capable of receiving light from both sides thereof.

### 2. Description of the Related Art

New energy technologies utilizing natural energy are attracting a lot of attention. As one of the technologies, there has been a growing interest on systems that utilize solar energy. In particular, solar power generation systems, which convert light energy into electric energy by using the photovoltaic effect, are widely used as means for obtaining clean energy.

Solar cells in which crystalline silicon is used for a solar cell element in order to increase the power have gone mainstream. So-called back contact solar cells, in which an n-type electrode and a p-type electrode are formed on the back side of a silicon substrate without forming an electrode on a light-receiving surface of the silicon substrate, are also in development.

For example, Japanese Unexamined Patent Application Publication No. 2012-99569 discloses a back contact solar cell in which an n-type electrode and a p-type electrode are disposed on the back surface of a silicon substrate so as to extend in the same direction. A back contact solar cell of this type is superposed on a wiring sheet to form a solar cell module.

A metal foil such as a copper foil, which is formed by using a plating method, is used as a wiring member of an existing wiring sheet. In order to reduce the electric resistance of the wiring member, the wiring member has a large width so that the wiring member can have a large cross-sectional area. In recent years, development of a bifacial solar cell, which can absorb light not only from a light-receiving surface of the solar cell but also from the back surface of the solar cell, and a bifacial solar cell module, which enables sunlight to be incident on the back side of the bifacial solar cell, is in progress.

The bifacial solar cell can receive a larger amount of light than a general monofacial solar cell and can improve conversion efficiency. However, there is a problem in that, when forming a bifacial solar cell module by using a combination of the back contact solar cell and the wiring sheet described in Japanese Unexamined Patent Application Publication No. 2012-99569, most of the back surface is covered by the metal foil, which is a wiring member, and it is difficult to increase the amount of light that is received on the back surface of the solar cell.

### SUMMARY

It is desirable to provide, by using a combination of a back contact solar cell and a wiring substrate that is capable of receiving light from both sides thereof, a bifacial solar cell module that takes into consideration absorption of light not only from a front surface on which an electrode is not formed but also from a back surface on which an electrode is formed.

According to an aspect of the disclosure, a bifacial solar cell module includes a semiconductor substrate; a plurality of back contact solar cells each of which includes an electrode on one surface of the semiconductor substrate; and a wiring substrate in which a plurality of wires are fixed to one surface of a wiring base member that is light transmissive. The plurality of solar cells are electrically connected to each other by the wires. In the bifacial solar cell module, the wires are conductors each of which has a circular cross-sectional shape; the wiring substrate includes a light-transmissive portion in which the wires are not disposed on the wiring base member; and each of the solar cells includes, in the one surface of the semiconductor substrate, a light-receiving region on which the electrode is not disposed.

### BRIEF DESCRIPTION OF THE DRAWINGS

FIG. 1 is a plan view of a solar cell that is included in a bifacial solar cell module according to a first embodiment of the present disclosure;

FIG. 2 is an enlarged sectional view of the bifacial solar cell module, taken along a plane perpendicular to electrodes of the solar cell;

FIG. 3 is a schematic sectional view of the bifacial solar cell module;

FIG. 4 illustrates the configuration of connections of wires to the solar cell in the bifacial solar cell module;

FIG. 5 is a plan view of an example of a wiring substrate that is included in the bifacial solar cell module;

FIG. 6 illustrates an example of arrangement of solar cells and wiring substrates in the bifacial solar cell module;

FIG. 7 illustrates another example of arrangement of solar cells and wiring substrates in the bifacial solar cell module;

FIG. 8 is a plan view of solar cells that are adjacent to each other, seen from a back side on which. electrodes are formed;

FIGS. 9A and 9B are sectional views illustrating a method of fixing a solar cell and a wiring substrate of the bifacial solar cell module to each other;

FIG. 10 is a plan view of the bifacial solar cell module according to the first embodiment of the present disclosure;

FIG. 11 is a plan view of a solar cell that is included in a bifacial solar cell module according to a second embodiment of the present disclosure;

FIG. 12 is a schematic sectional view of a bifacial solar cell module according to a third embodiment of the present disclosure; and

FIG. 13 is a schematic sectional view of another example of the bifacial solar cell module according to the third embodiment.

### DESCRIPTION OF THE EMBODIMENTS

Hereinafter, bifacial solar cell modules according to embodiments of the present disclosure will be described with reference to the drawings.

### First Embodiment

A bifacial solar cell module (hereinafter, simply referred to as “solar cell module”) according to a first embodiment includes a plurality of back contact solar cells 2 that are electrically connected to each other by using a wiring substrate 4.

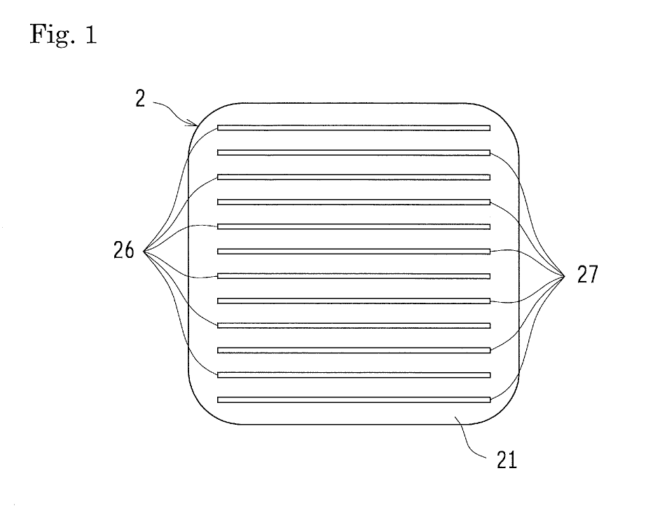

FIG. 1 is a plan view of a solar cell 2 that is included in a solar cell module 1 according to the first embodiment. FIG. 1 illustrates a surface on which electrodes are formed. In the following description of the embodiments, a surface of the solar cell 2 on which electrodes are disposed as shown in FIG. 1 will be referred to as “back surface”, and a surface opposite to the back surface will be referred to as “front surface”. If a frame (not shown) is attached to the outside edge of the solar cell module 1, a module including the frame will be referred to as “solar cell module 1”. In a silicon substrate 21, a surface on which electrodes are disposed will be referred to as “back surface” (the back surface of the solar cell 2), and a surface opposite to the back surface will be referred to as “front surface”, which faces in a direction from which sunlight is received.

As illustrated in FIG. 1, on the back surface of the silicon substrate 21, a plurality of n-type electrodes (first electrodes) 26 and a plurality of p-type electrodes (second electrodes) 27 are alternately arranged respectively at predetermined intervals. The n-type electrodes 26 and the p-type electrodes 27 each have a uniform width over the entire length thereof, and the pitches of the electrodes are substantially regular. In the back surface of the silicon substrate 21, a region between the n-type electrodes 26 and the p-type electrodes 27, where electrodes are not formed, is a back-side light-receiving region, which can generate electric power by receiving light entered. from the back side.

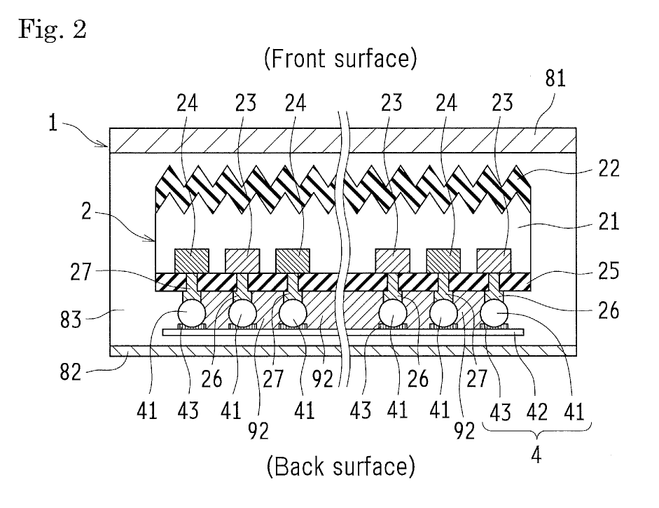

FIG. 2 is an enlarged sectional view of the solar cell module 1, taken along a plane perpendicular to the electrodes of the solar cell 2 shown in FIG. 1. The front surface of the back contact solar cell 2 has a protruding/recessed shape, which is formed on the front surface of the silicon substrate 21 as a structure for suppressing reflection of light. Moreover, an antireflection film 22 is formed on the front side of the silicon substrate 21. The protruding/recessed shape may be formed also on the back-side light-receiving region on the back side of the silicon substrate 21.

As the silicon substrate 21, for example, a substrate that is made from polycrystalline silicon, monocrystalline silicon, or the like that has either n-type conductivity or p-type conductivity may be used. The thickness of the silicon substrate 21 may be approximately 50 μm or larger and 400 μm or smaller. As the antireflection film 22, a film made of silicon nitride may be used.

A passivation film 25 may be formed on the back side of the silicon substrate 21. As the passivation film 25, a film made of silicon oxide may be used. However, the passivation film 25 disposed on the silicon substrate 21 is not limited to this. For example, a silicon nitride film, a silicon oxide film, an aluminum oxide film, or a laminate of these may be used. The passivation film 25 can suppress recombination of positive holes and electrons at the interface between silicon and electrodes on the back side of the solar cell 2, and can reduce electric-power generation loss.

The solar cell 2 is a bifacial solar cell that generates electric power by allowing light to enter also from the back surface thereof. In a case where the passivation film 25 is disposed on the back side, the passivation film 25 on the back-side light-receiving region need to transmit light. In this case, the passivation film 25 may have an extinction coefficient of 0.05 or lower for light whose wavelength is 400 nm or larger, and may have a thickness in the range of 10 nm to 100 nm.

Thus, the passivation film 25 has both of sufficiently high light transmissivity and passivation performance, and the solar cell 2 can receive light not only from the front side but also from the back side. In order to more efficiently generate electric power by receiving light from the back side, the silicon substrate 21 may have a protruding/recessed shape on the back side thereof.

At positions inside the silicon substrate 21 and adjacent to the back side, n-type impurity diffused regions 23, which include an n-type impurity such as phosphorus, and p-type impurity diffused regions 24, which include a p-type impurity such as boron or aluminum, are formed.

Inside the silicon substrate 21, which has n-type or p-type conductivity, a plurality of pn junctions are formed at the interfaces between the n-type impurity diffused regions 23 or the p-type impurity diffused regions 24 and the silicon substrate 21. Contact holes are formed by removing parts of the passivation film 25. Via the contact holes, the n-type electrodes 26 (first electrodes), which are connected to the n-type impurity diffused regions 23, and the p-type electrodes 27 (second electrodes), which are connected to the p-type impurity diffused regions 24, are disposed on the back surface of the silicon substrate 21.

As the material of the n-type electrodes 26 and the p-type electrodes 27, for example, a metal such as Ag, Ti/Pd/Ag, T/W/Cu, Ni/Cu, or the like may be used. Electrons and positive holes, which are generated at the pn junctions due to light entered from the front side and the back side of the solar cell 2, can be output as an electric current to the outside via the n-type electrodes 26 and the p-type electrodes 27. The passivation film 25 described above need not be disposed on the back side of the silicon substrate 21.

As illustrated in FIG. 2, the wiring substrate 4, in which wires 41 are fixed onto a wiring base member 42 by adhesives 43, is disposed on the back side of the solar cell 2. The solar cell 2 and the wiring substrate 4 are fixed to each other in a state in which the n-type electrodes 26, the p-type electrodes 27, and the wires 41 are in contact with each other.

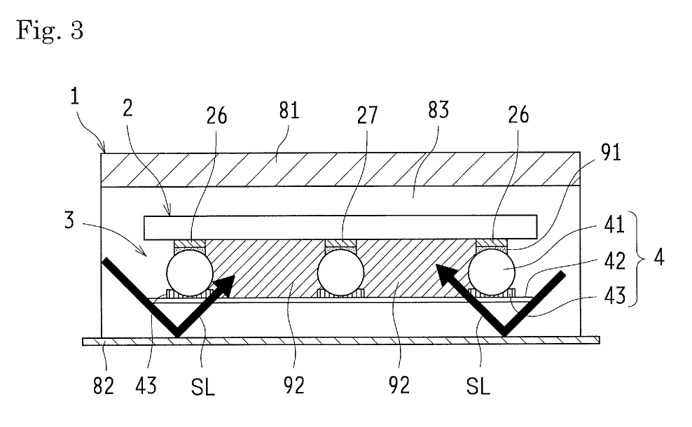

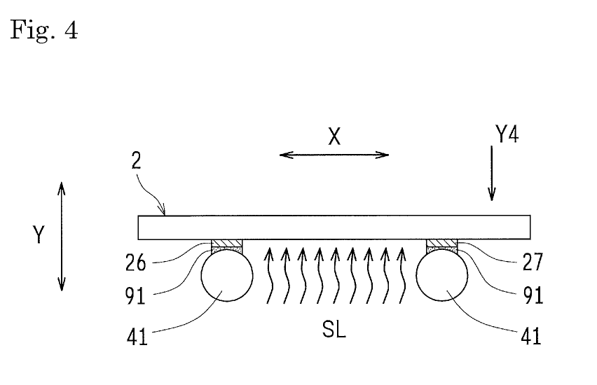

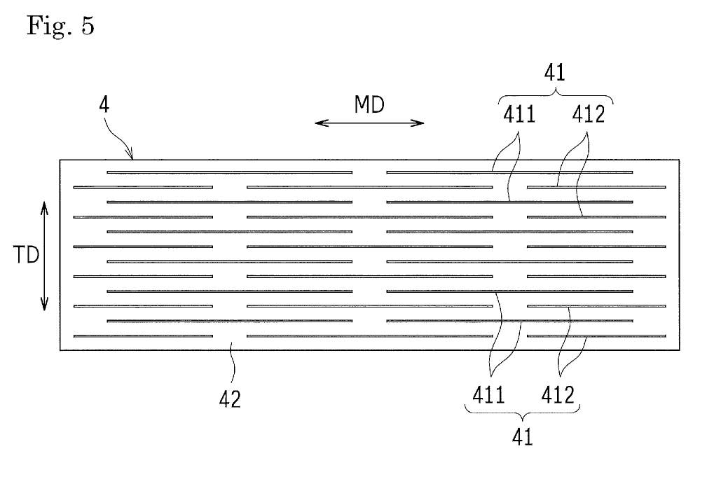

FIG. 3 is a schematic sectional view of the solar cell module 1 according to the first embodiment. FIG. 3 illustrates in more detail a portion that is related to a structure for fixing the solar cell 2 and the wiring substrate 4 shown in FIG. 2 to each other. FIG. 4 is a partial sectional view illustrating the configuration of connections of the wires 41 to the solar cell 2. FIG. 5 is a plan view of an example of the wiring substrate 4 that is included in the solar cell module 1.

As illustrated in FIG. 3, in the solar cell module 1, the solar cell 2 is fixed to the wiring substrate 4 by using a fixing resin 92 and the like. A space between a light-transmissive base member 81 and a back-side protective member 82 is sealed with a sealing resin (sealing member) 83 that is light transmissive. The light-transmissive base member 81 is a plate-shaped member that is made of a light-transmissive material, such as glass or a transparent plastic. As the back-side protective member 82, a weather-resistant resin film or sheet is used. Alternatively, a plate-shaped member that includes glass, a plastic, a metal, or the like may be used. As the sealing resin 83, a thermoplastic resin, such as ethylene vinyl acetate (EVA) or polyolefin, may be used.

The n-type electrodes 26 and the p-type electrodes 27 on the back side of the solar cell 2 are electrically connected to the wires 41 of the wiring substrate 4. The wires 41 electrically connect two adjacent solar cells 2 to each other. As the wires 41, copper wires each of which has a circular cross-sectional shape are used. In this case, the phrase “the cross sectional shape of each of the wires 41 is a circular shape” means that the outer peripheral surface of each of the wires 41 is a curved surface that is rounded in the circumferential direction. The cross-sectional shape need not be a circle and may be an elliptical shape.

With an existing wiring member, such as a flat copper wire and copper foil wiring, the wiring member need to have a large width to increase the cross sectional area thereof in order to reduce the electric resistance. As a result, most of the back side is covered by the wiring member. In contrast, by using the wires 41, each of which has a circular cross section, as illustrated in FIG. 3, contact portions between the back-side electrodes of the solar cell 2 and the wires 41 canal be made similar to point contacts (contact points) in the cross-sectional direction. Therefore, compared with the existing wiring member, the area of a region through which light cannot enter can be considerably reduced, and the back-side light-receiving area can be increased.

As illustrated in FIG. 4, the n-type electrodes 26 and the p-type electrodes 27 may be configured in such a way that, when the solar cell 2 is seen to be projected in the direction of arrow Y4, the projection regions of the n-type electrodes 26 and the p-type electrodes 27 are included in the projection regions of the wires 41. This is achieved, for example, by making the width of each of the n-type electrodes 26 and the p-type electrodes 27 in the X-direction smaller than the diameter of each of the wires 41.

It is sufficient that the width of each of the n-type electrodes 26 and the p-type electrodes 27 in the X-direction is smaller than the maximum width of each of the wires 41 in the X-direction. When each of the wires 41 has a circular cross-sectional shape, the maximum width of the wire 41 in the X-direction coincides with the diameter of the wire 41. For example, when the cross-sectional shape of each of the wires 41 is an elliptical shape, if the elliptical shape is long in the X-direction, the maximum width of the wire 41 coincides with the length of the major axis; and, if the elliptical shape is short in the X-direction, the maximum width of the wire 41 coincides with the length of the minor axis. The width of each of the n-type electrodes 26 and the p-type electrodes 27 in the X-direction may be smaller than the maximum width thereof. As the width of each of the back-side electrodes decreases, the area of the back-side light-receiving region can be increased and the amount of light that can enter the light-receiving region can be increased. The width of each of the electrodes may be appropriately determined as long as the performances of the solar cell module, such as the strength of the electrodes and the contact resistance, do not deteriorate.

In the present embodiment, the width (length in the X-direction) of each of the n-type electrodes 26 and the p-type electrodes 27 is smaller than the diameter of each of the wires 41 (corresponding to the width of the wire 41; the length in the X-direction). For example, the width of each of the n-type electrodes 26 and the p-type electrodes 27 is 100 μm and is smaller than the width (diameter) of each of the wires 41, which is 120 μm. In this case, between the type electrodes 26 and the p-type electrodes 27 on the back side of the solar cell 2, a light-receiving region in which the wires 41 are not disposed is formed so as to correspond to the back-side light-receiving region, in which the electrodes are not disposed. In the light-receiving region, sunlight SL can enter widely.

The length of each of the wires 41 in the Y-direction of FIG. 4 (direction perpendicular to the front surface of the solar cell 2) can be made larger than that of a case where a metal foil is used. Therefore, even in consideration of the resistance against electric currents collected from the solar cell 2, the width of each of the wires 41 in the X-direction (direction parallel to the front surface of the solar cell 2) can be reduced.

Thus, a larger amount of sunlight SL can enter the solar cell 2 from the back side of the solar cell 2, and the light-receiving region of the solar cell 2 can be enlarged. Moreover, because copper wires each having a circular cross-sectional shape are used as the wires 41, sunlight SL that has entered the solar cell 2 can be diffused at the outer surfaces of the copper wires, and the amount of electric power generated on the back side of the solar cell 2 can be increased. Furthermore, because copper wires that are generally on the market can be used as the wires 41, the solar cell module 1 can be manufactured at low costs.

For example, printed electrodes using silver paste may be used as the n-type electrodes 26 and the p-type electrodes 27, and copper wires coated with solder may be used as the wires 41. In this case, it is possible to form solder connections by heating the n-type electrodes 26, the p-type electrodes 27, and the wires 41. Instead of metal joints, which are typically solder joints, the n-type electrodes 26 and the p-type electrodes 27, and the wires 41 can be connected to each other by using an electroconductive adhesive, an anisotropic conductive film (ACF), or an anisotropic conductive paste (ACP). If it is possible to form electrical connections by mutual contact, the n-type electrodes 26 and the p-type electrodes 27, and the wires 41 may be connected to each other by using only the fixing resin 92 described below without using joining members 91 such as solder.

In plan view of the back side, the solar cell 2 has a light-receiving region in which none of the n-type electrodes 26 (first electrodes), the p-type electrodes 27 (second electrode), and the wires 41 is not disposed. The area of the light-receiving region may be larger than or equal to 50% of the area of the solar cell 2. Thus, sunlight can enter the solar cell 2 from the side on which electrodes are formed, the amount of sunlight SL that enters from the back side of the solar cell 2 can be increased, and the electric-power generating region can be further enlarged. In view of enlarging of the electric-power generating region, the proportion of the area of the light-receiving region in the area of the solar cell 2 may be large, and, for example, the proportion may be in the range of 75 to 95%. If the proportion exceeds 95%, the region in which either of the n-type electrodes 26, the p-type electrodes 27, or the wires 41 is disposed is small (narrow), and this may raise concern over a negative effect of serial resistance. Therefore, the proportion may be smaller than or equal to 95%.

Wiring Substrate

In the solar cell module 1 according to the first embodiment, the configuration of connections of the wires 41 is realized by using the wiring substrate 4. As illustrated in FIG. 5, in the wiring substrate 4, the plurality of wires 41 are fixed onto the wring base member 42. The wiring substrate 4 has a shape that is elongated in a direction MD (left-right direction in FIG. 5), which corresponds to the direction in which the solar cells 2 are arranged. The n-type electrodes 26 and the p-type electrodes 27 of the plurality of arranged solar cells 2 are electrically connected to the wires 41.

As the wiring base member 42, for example, a light-transmissive insulating resin film, sheet, or plate, which is made of, for example, polyester, such as polyethylene naphthalate (PEN) or polyethylene terephthalate (PET), or polyimide, is used. For example, a resin sheet that has a thickness of about 75 μm and that is mainly composed of PET may be used as the wiring base member 42, and copper wires each having a diameter of about 150 μm may be used as the wires 41.

The resin material of the wiring base member 42 may have heat resistance that can withstand a temperature higher than the softening temperature of the adhesives 43. With the resin material, it is possible to suppress large deformation of the wiring base member 42 when performing sealing, to reduce variations in the positions of the wires 41 on the wring base member 42, and to keep high quality connections between the solar cell 2 and the wiring substrate 4.

For example, the wiring base member 42 may be made of a material that does not melt at a processing temperature in the range of 130° C. to 180° C., because the wiring base member 42 need to keep the wiring configuration in a heating and pressing step for lamination and the like. The melting point of the material may be higher than the processing temperature by 50° C. or more. The melting point of both of the aforementioned polyethylene naphthalate and polyethylene terephthalate is 260° C.

As long as the wiring base member 42 is light transmissive and electrically insulating, the material of the wiring base member 42 is not limited to a resin. For example, a glass plate may be used, or a light-transmissive reinforced resin in which a transparent resin and transparent glass fibers are combined, may be used. The adhesives 43, which fix the wires 41 to the wiring base member 42, may be light transmissive, because light-transmissive adhesives can increase the amount of light that enters from the back surface.

The wires 41 extend in the longitudinal direction of the wiring substrate 4 and include first wires 411 and second wires 412. The first wires 411 and the second wires 412 each extend in the direction MD so as to correspond to the n-type electrodes 26 and the p-type electrodes 27 of each of the solar cells 2, which are to be disposed thereon.

The first wires 411 and the second wires 412, each of which is a copper wire having a circular cross-sectional shape, are affixed to the front surface of the wiring base member 42 by the adhesives 43 and form a wiring pattern. The first wires 411 and the second wires 412 are alternately arranged at regular intervals in a direction TD, which a direction that intersects the direction MD.

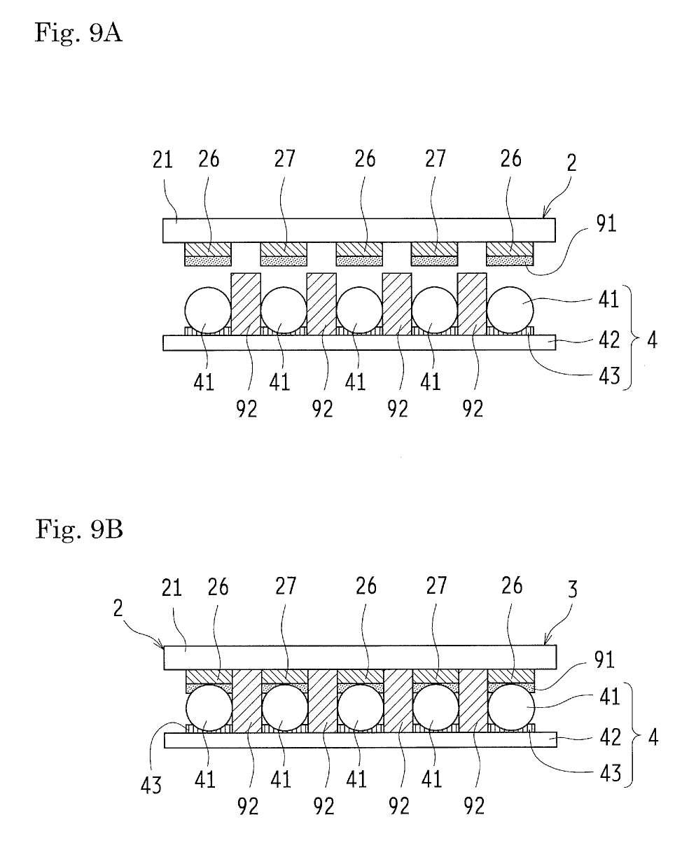

Each of the first wires 411 is partially embedded in the adhesive 43, which is formed on the wiring base member 42; and not only a lower surface thereof but also a part of both side surfaces thereof are in contact with the adhesive 43 (see FIG. 9A). The same applies to the second wires 412.

In a case where a resin film is used as the wiring base member 42 of the wiring substrate 4, when producing the resin film while rolling up the resin film, thermal contraction of the resin film in the direction MD (winding direction) and thermal contraction of the resin film in the direction TD (direction that intersects toe direction MD) differ from each other by several times to several tens of times. For example, when a general PET film is heat-treated for 30 minutes at 150° C., thermal contraction in the direction MD is about 2%, and thermal contraction in the direction TD is about 0.2%. In consideration of this fact, by selecting a direction in which the electrode pattern is fine and the design margin is small as the direction TD, it is possible to sufficiently reduce the effect of thermal contraction on the wiring base member 42. Alternatively, glass or a light-transmissive reinforced resin in which a transparent resin and transparent glass fibers are combined, each of which has smaller thermal contraction than a film-shaped base member such as a PET film, may be used.

In the wiring substrate 4, the number of the first wires 411 and the number of the second wires 412 may be appropriately determined in accordance with the shape and the size of each of the n-type electrodes 26 and the p-type electrodes 27 of the solar cell 2. For example, the adhesives 43 are applied onto the wiring base member 42, and the wires 41 are placed in the same number and at the same intervals as the electrodes of the solar cells. Subsequently, when the solar cells are arranged, a wiring pattern can be formed by partially cutting the wires 41 by using a laser or the like so that adjacent solar cells are electrically connected to each other in series.

For the wiring substrate 4, in the solar cell module 1 according to the present embodiment, a plurality of solar cells 2 are disposed adjacent to each other on the wiring substrate 4.

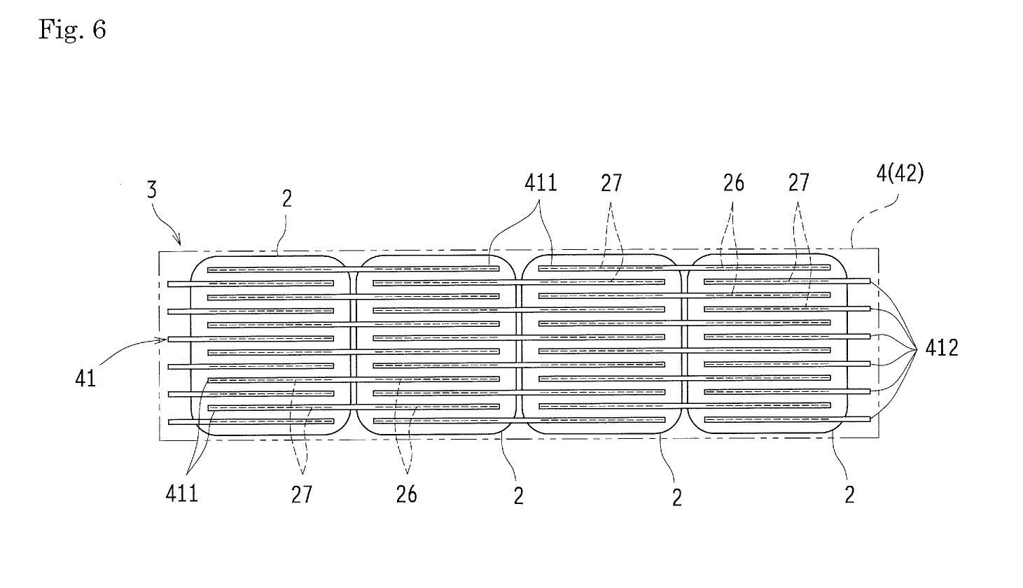

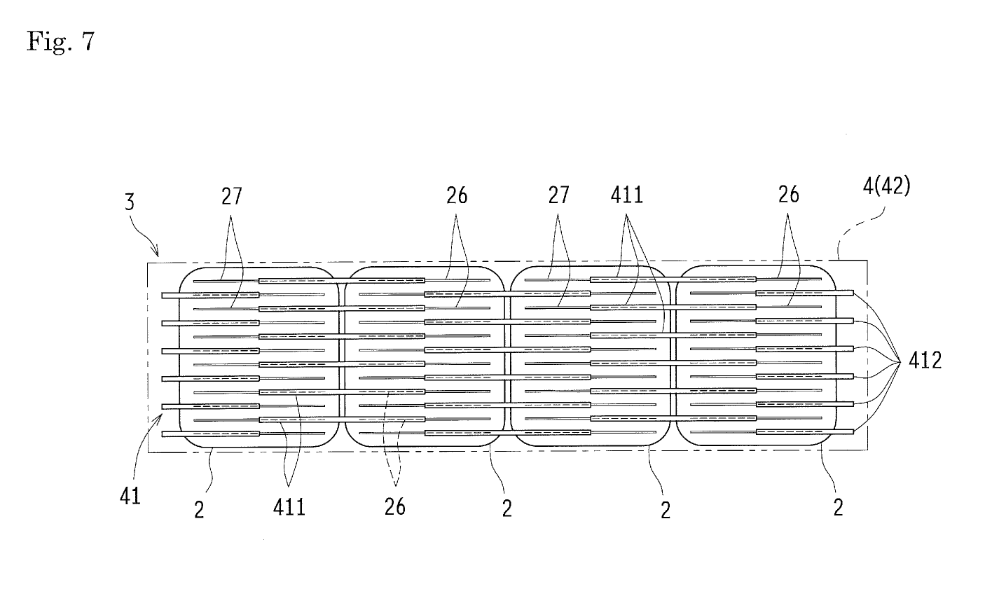

FIGS. 6 and 7 illustrate examples of arrangement of the solar cells 2 and the wiring substrates 4. These figures illustrate arrangements of the first wires 411 and the second wires 412 of the wiring substrate 4 on the back side of the solar cells 2, as seen from the back side of the wiring substrate 4 and the solar cells 2.

As illustrated in the figures, each of the solar cells 2 has a plurality of n-type electrodes 26 and a plurality of p-type electrodes 27 on the back side thereof. The n-type electrodes 26 and the p-type electrodes 27 of adjacent solar cells are connected to each other by the wires 41 of the wiring substrate 4. Thus, the adjacent solar cells 2 are connected to each other. In the present embodiment, the n-type electrodes 26, the p-type electrodes 27, and the wires 41 are linearly arranged.

In a case of forming a wiring pattern using copper wires, in contrast to an existing wiring pattern that is formed by patterning flat copper wires or copper foils, it is difficult to bend the copper wires beforehand and to bond the copper wires onto the wiring base member 42. However, with the present embodiment, because the wires 41 have a linearly arranged wiring pattern, even when copper wires each of which has a circular cross-sectional shape are used as the wires 41, it is possible to easily perform bonding of the wires 41.

Moreover, because of the linear arrangement, it is possible to bond the copper wires, which have been linearly extended, directly onto the wiring base member 42 and to fix the copper wires as the wires 41. After the wires 41 have been fixed, by removing parts of the wires 41 at predetermined positions by laser processing, machining, or the like, the wires 41 can be easily divided into the first wires 411 and the second wires 412.

In the configuration illustrated in FIG. 6, the wiring substrate 4 connects the n-type electrodes 26 of one of adjacent solar cells 2 and the p-type electrodes 27 of the other solar cell 2. Among the wires 41 of the wiring substrate 4, the first wires 411 are connected to the n-type electrodes 26 of one solar cell 2 and to the p-type electrodes 27 of an adjacent solar cell 2. The second wires 412 are connected to the p-type electrodes 27 of one solar cell 2 and to the n-type electrodes 26 of an adjacent solar cell 2.

In FIG. 6, the length of each of the wires 41 of the wiring substrate 4 is the same as the length from one end portion of the n-type electrode 26 to the other end portion of the p-type electrode 27 of an adjacent solar cell 2. Although the length of each of the wires 41 is not particularly limited, due to the structure illustrated in FIG. 6, it is possible to collect electric currents from the entireties of the solar cells 2 through the wires 41, which have lower electric resistance than the n-type electrodes 26 and the p-type electrodes 27. Thus, resistance loss that occurs when collecting electric currents can be suppressed, and the electric-current-collecting efficiency can be improved.

Because the wires 41 are disposed from one end portions to the other end portions of the n-type electrodes 26 and the p-type electrodes 27, electric currents collected from the solar cells 2 can flow through the wires 41. Moreover, it is not necessary to reduce the resistances of the n-type electrodes 26 and the p-type electrodes 27 in the longitudinal direction of the wires 41, and it is possible to reduce the thicknesses of the electrodes and to reduce the amount of expensive electrode materials used. Although light is not expected to enter the regions on which electrodes are disposed on the back surfaces of each of the solar cells 2, because the wires 41 are superposed on the electrodes so as to extend along the entirety of the electrodes, the solar cell 2 can have a sufficiently large light-receiving region without considerably reducing the area of the back-side light-receiving region due to the wires 41.

In the configuration illustrated in FIG. 7, the wiring substrate 4 connects the n-type electrodes 26 of one of adjacent solar cells 2 and the p-type electrodes 27 of the other solar cell 2. In this case, the wires 41 are disposed from the centers of the n-type electrodes 26 to the centers of the p-type electrodes 27 of an adjacent solar cell 2. That is, for example, the first wires 411 of the wiring substrate 4 are connected from the centers of the n-type electrodes 26 of one solar cell 2 to the centers of the p-type electrodes 27 an adjacent solar cell 2.

The wires 41 of the wiring substrate 4 (the first wires 411 and the second wires 412) connect electrodes, having different polarities, of adjacent solar cells 2 to each other; this connection is repeated in the cell-arrangement direction; and thereby the plurality of solar cells 2 are electrically connected in series. In consideration of balance between electric-current-collecting efficiency and electric-power generation efficiency, the area of the region in which the back-side electrodes and the wires 41 overlap may be adjusted as appropriate, in order that the solar cell module 1 can have the maximum electric-power generation performance.

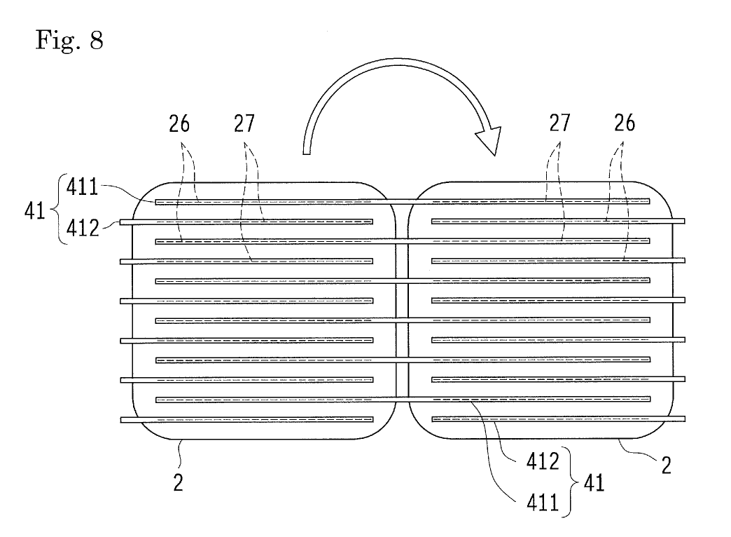

FIG. 8 is a plan view of two solar cells 2 that are adjacent to each other, seen from the back side on which electrodes are formed. The n-type electrodes 26 and the p-type electrodes 27 may be disposed in such a way that, when the solar cells 2 are rotated by 180° in the substrate plane, the positions of the n-type electrodes 26 and the p-type electrodes 27 are interchanged with each other. By arranging the electrodes of all of the solar cells 2 in this way, when the solar cells 2, which are to be connected in series, are placed so as to be alternately rotated by 180°, it is possible to connect the n-type electrodes 26 and the p-type electrodes 27 by linearly using copper wires or the like, which are the wires 41. In this case, not only the production efficiency is increased but also stress load on the wires 41 is reduced, and therefore the reliability of wiring between the solar cells 2 is improved.

Here, the phrase “the positions of the n-type electrodes 26 and the p-type electrodes 27 are interchanged with each other” is not intended to mean that the positions of the n-type electrodes 26 and the p-type electrodes 27 completely coincide when the solar cells 2 are rotated by 180° in the substrate plane, but may mean that at least a half of the positions of the electrodes overlap.

In a case where the n-type electrodes 26 and the p-type electrodes 27 are alternately arranged in one direction in the substrate plane of the solar cells 2, the positions of at least either the n-type electrodes 26 or the p-type electrodes 27 may be interchanged with each other by rotating the solar cells 2 by 180° in the substrate plane.

Method of Fixing Wiring Substrate and Solar Cell

A method of fixing the back contact solar cell 2 and the wiring substrate 4 to each other in the first embodiment will be described with reference to the drawing. FIGS. 9A and 9B are sectional views illustrating the method of fixing the solar cell 2 and the wiring substrate 4 to each other. In FIGS. 9A and 9B, the first wires 411 and the second wires 412 on the wiring substrate 4 will not be discriminated from each other and collectively referred to as the wires 41.

As illustrated in FIG. 9A, the solar cell 2 and the wiring substrate 4 are disposed so as to face each other. The wires 41 of the wiring substrate 4 are disposed at positions that correspond to the electrode patterns of the n-type electrodes 26 and the p-type electrodes 27 of the solar cell 2. The wires 41 of the wiring substrate 4 each have a circular cross section and are fixed onto the wiring base member 42 by using the adhesives 43. The wires 41, which include the first wires 411 and the second wires 412, are arranged at the same pitch as the n-type electrodes 26 and the p-type electrodes 27.

Uncured fixing resins 92, such as insulating adhesives, are disposed between the plurality of wires 41. The fixing resins 92, which fix the wiring base member 42 and the solar cell 2, are placed in at least a part of a region of the wiring base member 42 on which the wires 41 are not disposed. The fixing resins 92, which are adhesives for fixing the wiring base member 42 and the solar cell 2, are light transmissive when the solar cell module is completed.

The adhesives 43 and the fixing resins 92 may be made of the same material or may be made of different materials. The adhesives 43, which fix the wires 41, may have high heat resistance in an uncured state so that the adhesives 43 can keep the fixed positions of the wires 41 with high precision; and, for example, the adhesives 43 may be made of a thermosetting resin that does not soften when heated. Alternatively, the adhesives 43 may be a sticky substance that can fix the positions of the wires 41, each of which has a circular cross-sectional shape, without displacement by only pressing the wires 41 onto the wiring base member 42. The fixing resins 92 may be placed on the back-side light-receiving region of the back surface of the solar cell 2 on which electrodes are not formed.

Examples of a method of placing the fixing resins 92 include screen printing, dispenser application, and inkjet application. Among these, screen printing may be used. With such a method, the fixing resins 92 can be placed with ease, at low costs, and in a short time.

The fixing resins 92 may be disposed only on the back-side light-receiving region between the n-type electrodes 26 and the p-type electrodes 27 of the solar cell 2. In this case, the fixing resins 92 do not enter the spaces between the n-type electrodes 26 and the p-type electrodes 27, and the wires 41; and the stability of electrical connection between the electrodes of the solar cell 2 and the wires of the base member can be improved.

The fixing resins 92 may be placed between the n-type electrodes 26 and the p-type electrodes 27 of the solar cell 2 and between the wires 41 of the wiring substrate 4.

As each of the fixing resins 92, a resin that can be B-staged may be used. The phrase “resin that can be B-staged” refers to a resin having the following property: when an uncured fixing resin 92 in a liquid state is heated, the viscosity of the resin increases and the resin enters a cured state (first cured state); subsequently, when the temperature rises, the viscosity decreases and the resin softens; and subsequently, when the temperature rises further, the viscosity increases again and the resin enters a cured state (second cured state).

The uncured fixing resins 92, which are disposed between the wires 41, are cured to enter the first cured state. The uncured fixing resins 92 are cured, for example, by being heated or irradiated with light, such as ultraviolet rays, and enter the first cured state. Thus, the fixing resins 92 in the first cured state, in which the adhesion and fluidity thereof are lower than those in the uncured state, can be obtained.

Each of the fixing resins 92 in the first cured state may have a viscosity that is higher than that in an uncured state at room temperature (about 25° C.) and a shape-keeping property (of not being deformed provided that an external force is not applied), and may be in a low-adhesion state (a state of having adhesion with which the fixing resin 92 does not adhere even when the solar cell 2 or the wiring substrate 4 contacts a surface of the fixing resin 92). In this case, it is possible to use a highly-productive printing method in the step of placing the joining members 91 described below.

When causing the uncured fixing resin 92 to enter the first cured state by heating the fixing resin 92, the heating temperature may be lower than a temperature at which the fixing resin 92 in the first cured state softens as described below and a temperature at which the state of the fixing resin 92 changes from the softened state to the second cured state. By controlling the heating temperature, the uncured fixing resin 92 is prevented from entering the softened state or the second cured state.

The joining members 91 are placed on the surfaces of the n-type electrodes 26 and the p-type electrodes 27 of the solar cell 2. As the material of the joining members 91, a material including an electroconductive substance, such as solder, can be used. The joining members 91 may be placed, for example, by using a method such. as screen printing, dispenser application, or inkjet application. Instead of placing the joining members on the electrodes of the solar cell, wires 41 that have been plated with solder beforehand may be used.

The joining members 91 may be omitted, if connection by using the fixing regions 92 enables electrical connection between the back-side electrodes (the n-type electrodes 26 and the p-type electrodes 27) and the wires 41 on the wiring substrate 4, which are in contact with each other. Each of the joining members 91 and the fixing resins 92 need not be disposed over the entire region in which it is placed, and may be disposed only in a part of the region.

As illustrated in FIG. 9B, the solar cell 2 is disposed (superposed) on the wiring substrate 4. The solar cell 2 is superposed on the wiring substrate 4 in such a way that the n-type electrodes 26 and the p-type electrodes 27 of the solar cell 2 face the wires 41 with the joining members 91 therebetween.

The solar cell 2 and the wiring substrate 4, which have been superposed on each other, are affixed to each other by heating and pressing the solar cell 2 and the wiring substrate 4 or by irradiating the solar cell 2 and the wiring substrate 4 with light. The fixing resins 92, which have been in the first cured state, decrease in viscosity and enter a softened state.

The softened fixing resins 92, which are located between the n-type electrodes 26 and the p-type electrodes 27 of the solar cell 2, deform between the solar cell 2 and the wiring base member 42 of the wiring substrate 4, and enter the spaces between the wires 41. The electroconductive substance in the joining members 91 also softens by being heated, and deforms between the electrodes of the solar cell 2 and the wires 41 of the wiring base member 42.

The softened fixing resins 92 increase further in viscosity by being heated or irradiated with light such as ultraviolet rays, cure again, and enter the second cured state. Because the second cured state is a state in which the resins have cured due to cross-linking reaction, the fixing resins 92 do not soften again and enter a stably cured state. Thus, the solar cell 2 and the wiring substrate 4 can be joined to each other with high precision and with strength.

When the solar cell 2 and the wiring substrate 4 are joined to each other as described above, the n-type electrodes 26 and the p-type electrodes 27 and the plurality of wires 41 are electrically connected to each other, and thereby a solar cell string 3 can be formed. By press-bonding the wiring substrate 4, in which the plurality of wires 41 are fixed, and a plurality of solar cells 2 to each other, it is possible to simultaneously perform wiring and connection between adjacent solar cells 2. As a result, the production efficiency is considerably improved.

By using the wiring substrate 4, even when copper wires each of which has a circular cross-sectional shape are used as the wires 41, it is possible to increase positional precision when connecting the back-side electrodes of the solar cell 2 and the wires 41 to each other. For example, with an existing interconnector that is formed of a flat copper wire, positional displacement does not occur even if the interconnector is placed on a flat surface, and the interconnector can be held with high positional precision by using a robot arm having a suctioning portion. On the other hand, the position of a copper wire, which easily on a flat surface, is instable, and it is difficult to hold the copper wire even with a suctioning portion of a robot arm.

However, with the present disclosure, because the wires 41 have been fixed onto the wiring base member 42 beforehand, displacement of copper wires can be suppressed, and the solar cell 2 and the wiring substrate 4 can be connected to each other with high positional precision. By using the wires 41 each of which has a circular cross-sectional shape, the amount of light that enters the back-side light-receiving region of the solar cell 2 can be increased while suppressing the wiring resistance. As a result, a high-efficiency bifacial solar cell module including the back contact solar cell 2 is realized.

In a state in which the solar cell 2 and the wiring substrate 4 are fixed to each other by the fixing resins 92, a sealing step of sealing the solar cell string 3 is performed, and the joining members 91 melt due to heat in the sealing step. Therefore, the n-type electrodes 26 and the p-type electrodes 27 of the solar cell 2 and the wires of the wiring base member 42 can be electrically connected to each other very easily and reliably. Because the wiring base member 42 and the sealing member are independent from each other, even when the sealing member softens and melts in the sealing step, the positions of the wires 41 fixed onto the wiring base member 42 are not considerably displaced, and the high positional precision of connection between the back-side electrodes of the solar cell 2 and the wires 41 can be maintained.

Solar Cell Module

As illustrated in FIGS. 2 and 3, in the solar cell module 1, the light-transmissive base member 81, the sealing resin 83, the solar cell string 3, the sealing resin 83, and the back-side protective member 82 are stacked. The solar cell module 1 is sealed by being heated and pressed. Heating is performed, for example, at 160° C.

By performing heating in the stacked state, the sealing resin 83, which is a thermoplastic resin, softens, and then cures by being cooled. When the sealing resin 83 cures, the electrodes of the solar cell 2 and the wires 41 of the wiring substrate 4 are mechanically press-bonded to each other, and the electrical connection becomes more reliable. Thus, the light-transmissive base member 81, the solar cell 2, the wiring substrate 4, and the back-side protective member 82 are integrated into the solar cell module 1.

The solar cell 2 and the wiring substrate 4 are disposed between the light-transmissive base member 81 and the back-side protective member 82. A space between the light-transmissive base member 81 and the back-side protective member 82 is sealed with the sealing resin 83. The sealing resin 83 and the wiring base member 42 are light transmissive, and the back-side protective member 82 is light reflective.

Sunlight SL that has been reflected by the back-side protective member 82 is incident on the back side of the solar cell 2. Because the wiring base member 42 of the wiring substrate 4 and the fixing resin 92 are light transmissive, the sunlight SL that is incident on the back side can enter the solar cell 2.

Because the solar cell 2 has a bifacial structure that allows light to enter from both of the front and back surfaces thereof, it is possible to increase the electric-power generation efficiency of the solar cell module 1. The wires 41 of the wiring substrate 4, each of which has a circular cross-sectional shape, can reduce resistance loss while suppressing the projection area thereof relative to the solar cell 2. Moreover, because the surface of each of the wires 41 is a curved surface, the surface can diffuse light entered from the back side and a part of the diffused light enters the back side of the solar cell 2, and thereby it is possible to increase the amount of electric power generated in the back-side light-receiving region.

When the wires 41 each have a circular cross-sectional shape, the area of contact between the n-type electrodes 26 and the p-type electrodes 27 is small. Therefore, displacement of the wires 41 and connection failure tend to occur. In particular, when the width of the wires 41 is maximally reduced as a bifacial solar cell 2, the allowance for displacement is low. However, in the solar cell module 1 according to the present embodiment, the wiring substrate 4, in which the wires 41 have been fixed beforehand to the wiring base member 42 by using the adhesives 43, is used. Thus, it is possible to connect the wires 41 and the n-type electrodes 26 and the p-type electrodes 27 to each other with high precision and to prevent occurrence of displacement and contact failure.

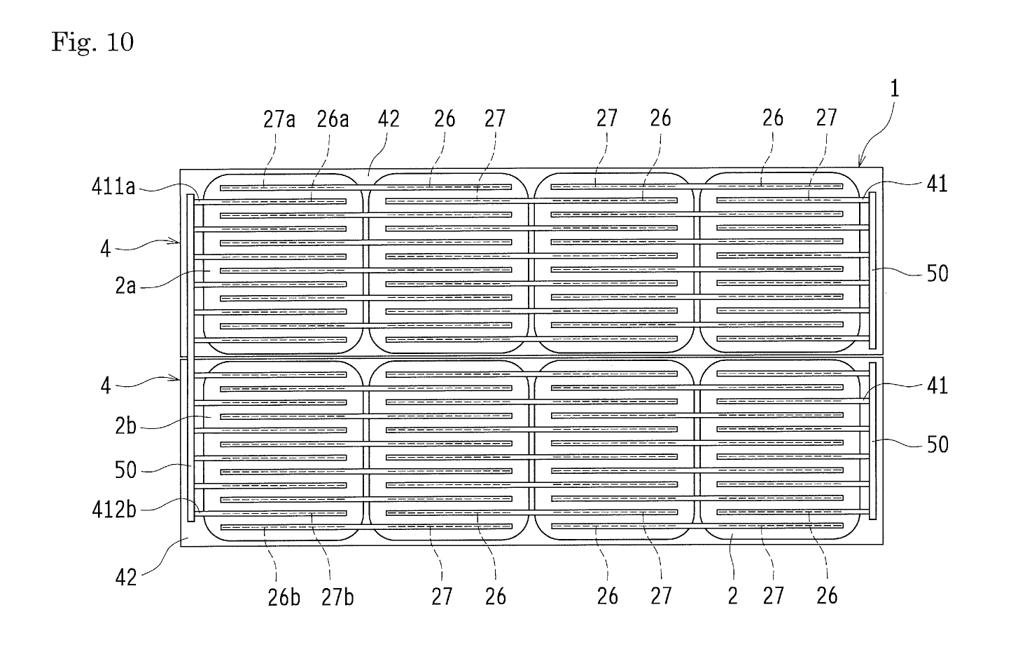

FIG. 10 is a plan view of an example of the solar cell module 1 according to the first embodiment of the present disclosure. FIG. 10 illustrates the solar cell module 1 as seen from the back side. In the solar cell module 1, a plurality of solar cells 2 are connected in series on the wiring substrate 4 in rows, and the rows are connected to each other in a direction that intersects the direction in which the solar cells 2 are connected in series.

For example, as illustrated in FIG. 10, from a solar cell 2a, which is disposed at the upper left corner of the wiring substrate 4, first wires 411a, which are connected to n-type electrodes 26a, extend toward a left end portion of the wiring base member 42. From a solar cell 2b, which is disposed at the lower left corner of the wiring substrate 4, second wires 412b, which are connected to p-type electrodes 27b, extend toward the left end portion of the wiring base member 42. The first wires 411a and the second wires 412b are electrically connected to each other by a busbar wire 50 by using an electroconductive member such as solder.

At the right end portion of the wiring substrate 4 illustrated in FIG. 10, the wires 41 extend towered the right end portion and busbar wires 50 are connected. The busbar wires 50 at the right end portion are connected to output wires (not shown) or the like for outputting an electric current generated by the solar cell module 1 to the outside.

Because the solar cell module 1 according to the present embodiment can function as a bifacial solar cell module with only sunlight from the direction in which the front surface of the solar cell 2 faces, the solar cell module 1 may be placed in the same way as an ordinary monofacial solar cell module. Therefore, the solar cell module 1 according to the present embodiment is suitable as a solar power generation system that is placed on the roof of a housing or a factory.

### Second Embodiment

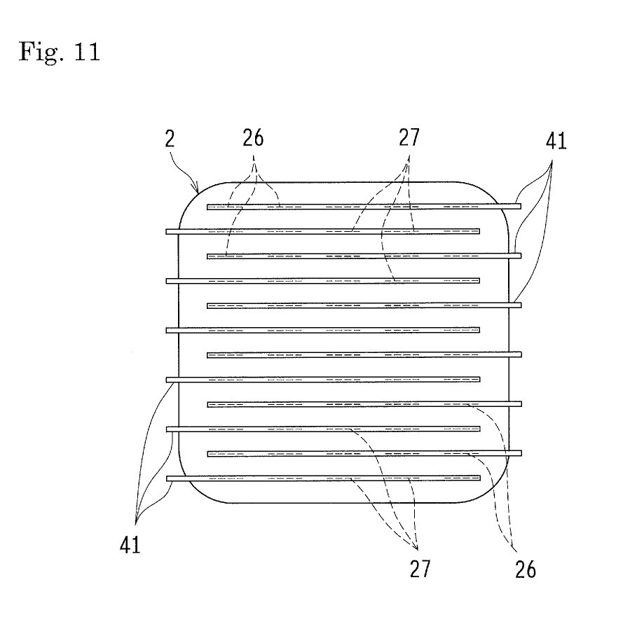

FIG. 11 is a plan view of a solar cell 2 that is included in a solar cell module 1 according to a second embodiment. The solar cell module 1 according to the present embodiment differs from the solar cell module 1 according to the first embodiment in the electrode pattern of the solar cell 2.

As illustrated in the figure, the n-type electrodes 26 and the p-type electrodes 27 are each divided into a plurality of insular portions, and the wires 41 are electrically connected to a plurality of insular n-type electrodes 26 and a plurality of insular p-type electrodes 27. By dividing each of the n-type electrodes 26 and the p-type electrodes 27 into a plurality of insular portions, the amount of electrode metal used can be reduced, the manufacturing costs of the solar cell 2 can be suppressed, the area of the back-side light-receiving region can be increased by reducing a region of the back surface of the solar cell 2 covered by the electrodes, and the electric-power generation efficiency can be improved.

The electrode pattern of the solar cell 2 included in the solar cell module 1 is not limited to those illustrated in FIGS. 1 and 11. For example, finger electrodes (not shown) may be connected across all of the n-type electrodes 26 and the p-type electrodes 27 shown in FIG. 1. The solar cell 2 may have any of various appropriate electrode patterns.

### Third Embodiment

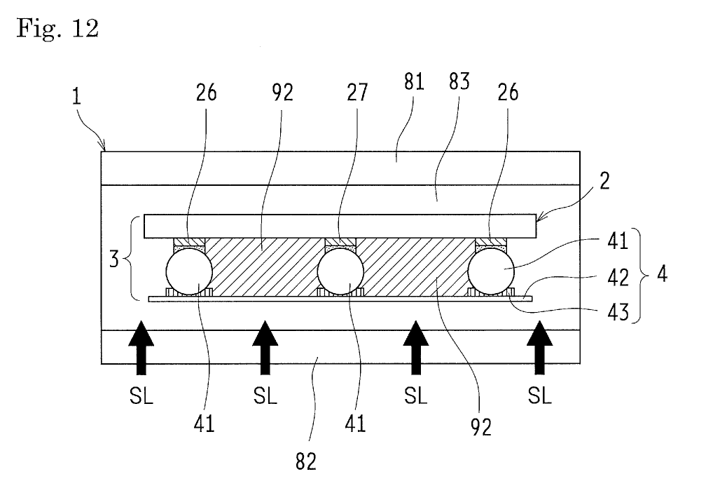

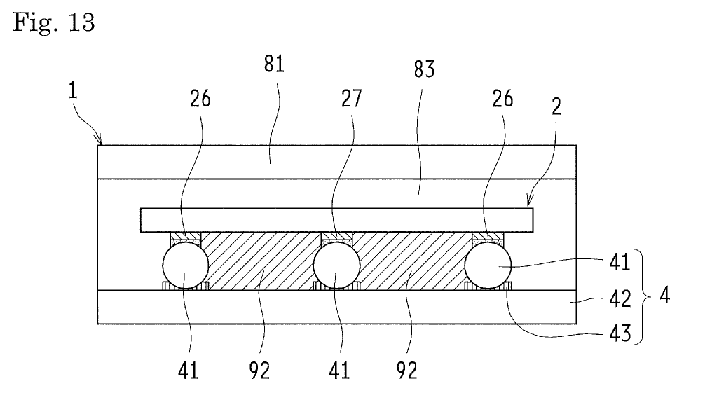

FIG. 12 is a schematic sectional view of a solar cell module 1 according to a third embodiment. FIG. 13 is a schematic sectional view of another example of a solar cell module 1 according to the third embodiment. In the solar cell module 1 according to the present embodiment, glass, which is a light-transmissive base member, is used as the back-side protective member 82.

In the solar cell module 1, the solar cell 2 and the wiring substrate 4 are disposed between the light-transmissive base member 81 (glass) and the back-side protective member 82 (glass). A space between the light-transmissive base member 81 (glass) and the back-side protective member 82 (glass) is sealed with a sealing resin 83 that is light transmissive. Accordingly, the sealing resin 83, the wiring base member 42, and the back-side protective member 82 (glass) are each light transmissive.

Although the sealing resin 83 is interposed between the wiring substrate 4 and the back-side protective member 82 (glass), the solar cell module 1 has a structure such that sunlight SL that has entered from the back side of the solar cell module 1 can pass through the back-side protective member 82 (glass) and the sealing resin 83 and can enter the solar cell 2. Thus, with the solar cell module 1, the amount of light that enters the solar cell 2 is increased, and the amount of generated electric power can be increased. The material of the back-side protective member 82 is not limited to glass, as long as the back-side protective member 82 is a plate-shaped member that is light transmissive. The material may be a transparent plastic such as PET.

As illustrated in FIG. 13, glass may be used as the wiring base member 42 of the wiring substrate 4. In this case, the glass of the wiring base member 42 can also function as the back-side protective member 82, so that the manufacturing costs can be suppressed.

The solar cell module according to the present embodiment can function as a bifacial solar cell module by receiving sunlight from both of the front surface and the back surface of the solar cell module. Therefore, the solar cell module according to the present embodiment is suitable as an industrial solar power generation system that is placed on a flat-roof or outdoors, for which the back side of the module is open and sunlight is expected to be incident on the back side; a power generation system that is placed vertically like a fence; a light-collecting solar power generation system; and the like.

### EXAMPLES

As an example of a bifacial solar cell module according to the present disclosure, a solar cell 2 and a wiring substrate 4 of a solar cell module 1 were formed as follows.

In the solar cell 2, the n-type electrodes 26 and the p-type electrodes 27 were formed on the back surface of the silicon substrate 21 so as to be arranged at an electrode pitch of 1.6 mm. That is, the n-type electrodes 26 and the p-type electrodes 27 were alternately arranged at intervals of 0.8 mm.

Copper wires each of which had a circular cross-sectional shape with a diameter of 170 μm were used as the wires 41. The copper wires each had a cross-sectional area of 0.0245 mm². In the solar cell module 1, the ratio of the width a region in which none of the wires 41, the n-type electrodes 26, and the p-type electrodes 27 was disposed and the width of a region in which any of these was disposed was 0.63 mm/0.17 mm.

As a comparative example, a wiring pattern was formed on the wiring substrate by using a copper foil having a thickness of 35 μm so as to have the same cross-sectional area as the copper wire according to the example. In this case, in a solar cell module including a wiring substrate according to the comparative example, the ratio of the width of a region in which none of the copper wires, the n-type electrodes, and the p-type electrodes was disposed and the width of a region in which any of these was disposed was 0.1 mm/0.7 mm.

Accordingly, it has been shown that, with the solar cell module 1 according to the example, the amount of sunlight SL that enters the solar cell 2 from the back side can be increased and the area of the electric-power generating region can be increased.

The present disclosure is not limited to embodiments of a solar cell module that have been described above, which can be modified in various ways within the scope of the claims, and the technical scope of the present disclosure includes embodiments that are obtained by using any appropriate combination of technical elements described in different embodiments. Moreover, a new technical feature can be formed by combining technical means disclosed in the embodiments.

The present application claims priority under 35 U.S.C. §119(a) to Japanese Patent Application. No. 2017-251075, filed Dec. 27, 2017, the contents of which are incorporated herein by reference in their entirety.

The present disclosure can be embodied in various other forms within the spirit and scope of thereof. Therefore, the embodiments described above are examples in all respects and should not be interpreted as limiting. The scope of the present disclosure is described in the claims and is not restricted at all by the description of the embodiments. Moreover, all modifications within the equivalents of the claims are included in the scope of the present disclosure.

What is claimed is:

1. A bifacial solar cell module comprising:
a semiconductor substrate;
a plurality of back contact solar cells each of which includes an electrode on one surface of the semiconductor substrate; and
a wiring substrate in which a plurality of wires are fixed to one surface of a wiring base member that is light transmissive,
wherein the plurality of solar cells are electrically connected to each other by the wires,
wherein the wires are conductors each of which has a circular cross-sectional shape,
wherein the wiring substrate includes a light-transmissive portion in which the wires are not disposed on the wiring base member, and
wherein each of the solar cells includes, in the one surface of the semiconductor substrate, a light-receiving region on which the electrode is not disposed.

2. The bifacial solar cell module according to claim 1,
wherein a light-transmissive fixing resin is disposed in at least a part of a space between the light-receiving region of each of the solar cells and the light-transmissive portion of the wiring substrate.

3. The bifacial solar cell module according to claim 1,
wherein an area of the light-receiving region is larger than or equal to 50% of an area of each of the solar cells.

4. The bifacial solar cell module according to claim 1,
wherein the electrode includes a first electrode and a second electrode whose polarities differ from each other, and
wherein the wires, the first electrode, and the second electrode are disposed in such a way that, when projected from the other surface of the semiconductor substrate, projection regions of the first electrode and the second electrode are included in projection regions of the wires.

5. The bifacial solar cell module according to claim 1,
wherein the electrode includes a first electrode and a second electrode whose polarities differ from each other, and
wherein the first electrode of one of the solar cells that are disposed adjacent to each other and the second electrode of the other solar cell are connected to each other by a corresponding one of the wires, and the second electrode of the one of the solar cells and the first electrode of the other solar cell are connected to each other by a corresponding one of the wires.

6. The bifacial solar cell module according to claim 5,
wherein the first electrode, the second electrode, and the wires are linearly arranged along one edge of each of the solar cells.

7. The bifacial solar cell module according to claim 6,
wherein each of the wires has a length that includes a length from one end portion of the first electrode of the one of the solar cells to the other end portion of the second electrode of the other solar cell.

8. The bifacial solar cell module according to claim 6,
wherein each of the wires is disposed from the first electrode of the one of the solar cells to the second electrode of the other solar cell.

9. The bifacial solar cell module according to claim 5,
wherein the first electrode and the second electrode are disposed in such a way that, when the solar cells that are adjacent to each other are rotated by 180° in a plane of the semiconductor substrate, positions of the first electrode and the second electrode on the solar cells are interchanged with each other.

10. The bifacial solar cell module according to claim 1,
wherein the solar cells and the wiring substrate are disposed between a light-transmissive base member and a back-side protective member and are sealed with a sealing resin that is light transmissive.

11. The bifacial solar cell module according to claim 10,
wherein the back-side protective member is light transmissive.
